(19) United States
(12) Patent Application Publication
(10) Pub. No.: US 2020/0401975 A1
(43) Pub. Date: Dec. 24, 2020

(54) ENERGY-EFFICIENCY ENHANCEMENT PLATFORM SYSTEM BASED ON SUBMETERING DATA

(71) Applicant: RETIGRID CO., LTD., Seoul (KR)

(72) Inventor: Young Ho AHN, Seoul (KR)

(21) Appl. No.: 16/902,586

(22) Filed: Jun. 16, 2020

(30) Foreign Application Priority Data
Jun. 18, 2019 (KR) 10-2019-0072505

(51) Int. Cl. G06Q 10/06; G06Q 50/06; G06Q 10/04; G01R 21/133

(52) U.S. Cl. CPC G06Q 10/06375; G06Q 50/06; G01R 21/133; G06Q 10/06315; G06Q 10/04

(57) ABSTRACT

Provided is an energy-efficiency enhancement platform system based on submetering data. The system includes a platform server through which a demand source that needs to enhance energy efficiency and a supply source that provides at least one of energy-efficiency enhancement equipment, an energy management system, and an energy analysis consulting service share submetering data. The platform server includes a data collection module that collects the submetering data that is data actually measured on a per-equipment basis from the demand source, a data provision module that provides the supply source with the collected submetering data, an analysis module that analyzes an energy-efficiency enhancement proposal received from the supply source and the collected submetering data, and an efficiency-enhancement proposal module that provides the demand source with an energy-efficiency enhancement plan on the basis of a result of the analysis by the analysis module.

### CROSS REFERENCE TO RELATED APPLICATION

The present application claims priority to Korean Patent Application No. 10-2019-0072505, filed Jun. 18, 2019, the entire contents of which is incorporated herein for all purposes by this reference.

### BACKGROUND OF THE INVENTION

### Field of the Invention

The present invention relates to an energy-efficiency platform system and, more particularly, to an energy-efficiency enhancement platform system based on submetering data.

### Description of the Related Art

South Korea is heavily dependent on imports for energy resources. At the time of writing, the price of crude oil was 100 dollars a barrel. Even in this high oil price situation, consumption of imported energy resources in South Korea has been increasing. To deal with this trend, technologies for enhancing energy efficiency to reduce consumption of energy resources have been developed. For example, technologies for reducing consumption of energy resources in buildings and technologies for precisely computing amounts of saving of energy have been developed.

Recently, energy performance improvement actions have been taken to reduce consumption of energy resources in buildings. Programs for quantitatively and qualitatively analyzing the energy saving results obtained by the energy performance improvement actions and programs for providing management indicators necessary to efficiently control energy consumption in buildings have been developed.

In addition, a supply source that provides energy efficiency enhancement equipment, an energy management system, an energy management program, or the like also provides these types of programs to a demand source that needs to enhance energy efficiency in various types of factories, buildings, or the like, in order to enhance the energy efficiency.

However, the existing energy efficiency enhancement market is not active due to a large expense (operating cost) of providing a one-to-one matching between the demand source and the supply source. More specifically, there are various technologies that are provided by sources, and there are problems in that pieces of information are unreliable, such as a cost of installing the energy efficiency enhancement equipment or the energy management system and an achievement. Because of this, the demand source has difficulty in selecting the supply source. In addition, the supply source has difficulty in precisely recognizing a characteristic of the demand source, and thus in developing business with the demand source. This incurs a high operating cost and increases an amount of purchase that is to be borne by the demand source. Therefore, there is a need to reduce the expense of providing the one-to-one matching between the demand source and the supply source through market innovation and market concentration. Furthermore, there is a need to develop technologies to expand the energy efficiency enhancement market and to encourage energy efficiency enhancement among a wide variety of demand sources.

Examples of the related art include Korean Unexamined Patent Application Publication No. 10-2017-0035261 titled “MATHOD AND APPARATUS FOR EVALUATING ENERGY EFFICIENCY ENHANCEMENT IN BUILDING” issued on Mar. 30, 2017, and Korean Unexamined Patent Application Publication No. 10-1931964 titled “METHOD OF COMPUTING AMOUNT OF SAVING OF ENERGY ACHIEVED THROUGH ENERGY PERFORMANCE IMPROVEMENT ACTION”, issued on Mar. 20, 2019.

### SUMMARY OF THE INVENTION

An objective of the present invention is to provide an energy-efficiency enhancement platform system in which, through a platform server, a demand source and a supply source share submetering data that is data actually measured on a per-equipment basis, thereby resolving information asymmetry. In the energy-efficiency enhancement platform system, the demand source needs to enhance energy efficiency and the supply source provides at least one of energy-efficiency enhancement equipment, an energy management system, and an energy analysis consulting service. With the energy-efficiency enhancement platform system, the supply source can recognize a characteristic of the demand source, and thus can precisely target a potential custom and can increase a business volume with keeping an operating cost low. Furthermore, the demand source can obtain energy-efficiency enhancement information on already-installed equipment, and thus can select an optimal solution and supply source at low cost and can prevent overlapping investments.

According to an aspect of the present invention, there is provided an energy-efficiency enhancement platform system based on submetering data, the system including: a platform server through which a demand source that needs to enhance energy efficiency and a supply source that provides at least one of energy-efficiency enhancement equipment, an energy management system, and an energy analysis consulting service share submetering data. In the energy-efficiency enhancement system, the platform server includes: a data collection module that collects the submetering data that is data actually measured on a per-equipment basis, from the demand source; a data provision module that provides the supply source with the collected submetering data; an analysis module that analyzes an energy-efficiency enhancement proposal received from the supply source and the collected submetering data; and an efficiency enhancement proposal module that provides the demand source with an energy-efficiency enhancement plan on the basis of a result of the analysis by the analysis module.

In the energy-efficiency enhancement platform system, the data provision module may provide the supplier with the collected submetering data, but the collected submetering data as non-identification data with which an individual demand source is unidentifiable.

In the energy-efficiency enhancement platform system, the data provision module may provide the supply source with the submetering data that results from categorization by at least one of a type of equipment, a type of business, and a rating.

In the energy-efficiency enhancement platform system, the analysis module may quantitatively analyze the energy-efficiency enhancement proposal received from the supply source, on the basis of the submetering data collected from the demand source, and the efficiency enhancement proposal module may propose to the demand source the energy-efficiency enhancement plan that includes a result of the quantitative analysis.

In the energy-efficiency enhancement platform system, the energy-efficiency enhancement plan may include a return on investment (ROI).

In the energy-efficiency enhancement platform system, the efficiency enhancement proposal module may provide the demand source with an energy-efficiency enhancement method and a result thereof for a type of business to which the demand source belongs.

In the energy-efficiency enhancement platform system, the energy-efficiency enhancement plan may include an energy-efficiency enhancement plan on a per-type-of-business basis and an energy-efficiency enhancement plan on a per-equipment basis, which are based on the submetering data.

The energy-efficiency enhancement platform system may further include a matching module that matches a demand source and a supply source selected by the demand source.

In the energy-efficiency enhancement platform system based on submetering data according to the embodiment of the present invention, the demand source and the supply source share submetering data that is data actually measured on a per-equipment basis, through a platform server, thereby resolving information asymmetry. In the energy-efficiency enhancement platform system, the demand source needs to encourage energy efficiency enhancement, and the supplier provides at least one of energy efficiency enhancement equipment, an energy management system, and an energy diagnosis consulting service. With the energy-efficiency enhancement platform system, the supply source can recognize a characteristic of the demand source, and thus can precisely target a potential custom and can increase a business volume with keeping an operating cost low. Furthermore, the demand source can obtain energy efficiency enhancement information on already-installed equipment, and thus can select an optimal solution and supply source at low cost and can prevent overlapping investments.

### BRIEF DESCRIPTION OF THE DRAWINGS

FIG. 1 is a diagram illustrating an energy-efficiency enhancement market in the related art;

FIG. 2 is a diagram illustrating an energy-efficiency enhancement platform system based on submetering data according to an embodiment of the present invention;

FIG. 3 is a diagram illustrating a configuration of the energy-efficiency enhancement platform system based on the submetering data according to the embodiment of the present invention;

FIG. 4 is a diagram illustrating the respective flows of data and a service between each constituent element of the energy-efficiency enhancement platform system based on the submetering data according to the embodiment of the present invention; and

FIG. 5 is a diagram illustrating a detailed configuration of the platform server in the energy-efficiency enhancement platform system based on the submetering data according to the embodiment of the present invention.

### DETAILED DESCRIPTION OF THE INVENTION

With reference to the accompanying drawings, preferable embodiments will be described below in enough detail to enable a person of ordinary skill in the art to which the present invention pertains to practice the present invention without undue experimentation. However, when the preferable embodiments of the present invention are described in detail, in a case where it is determined that detailed descriptions of functions and configurations known in the related art will unnecessarily make the nature and gist of the present invention unapparent, the detailed descriptions thereof are omitted. In addition, constituent elements that perform the same or similar functions or operations are given the same or similar reference characters throughout all the drawings.

In addition, when a constituent element is referred to as being “connected to” one other constituent element, the constituent element may be directly connected to one other constituent element or may be “indirectly connected to one other constituent with an intervening constituent element in between. In addition, when the expression “includes a certain constituent element”, unless specifically otherwise described, this means “may further include any other constituent”, not excluding any other constituent element.”

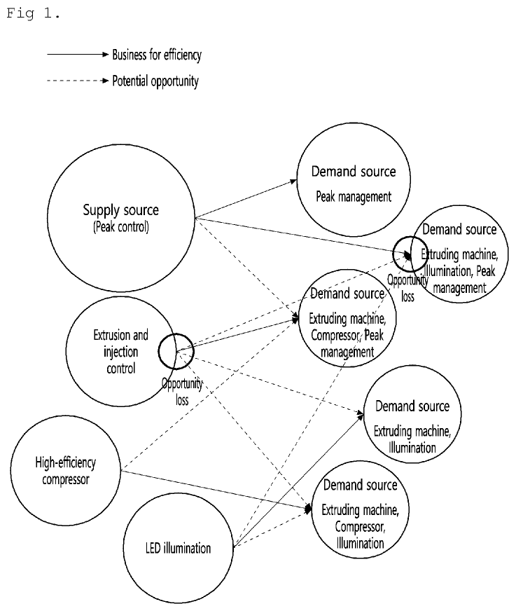

FIG. 1 is a diagram illustrating an energy-efficiency enhancement market in the related art. As illustrated in FIG. 1, in the energy-efficiency enhancement market in the related art, there is a bi-directional information asymmetry between a demand source and a supply source. That is, the supply source bears high survey and operating cost that occur due to a limited number of demand sources and expenses that increase due to inaccurate information. This increase in expenses leads to an increase in expenses that are to be borne by the demand source. Thus, an excessive investment cost is incurred, and overlapping investments in an Energy Management System (EMS) or the like are made. In addition, there are various technologies that are provided by the supply source, and there are problems in that pieces of information, such as an installation cost and an achievement in energy efficiency enhancement, are unreliable. Thus, the demand source has difficulty securing an optimal solution. In this manner, in an existing energy-efficiency enhancement market, both the demand source and the supply source suffer a monetary loss due to an increase in cost and losses of potential opportunities.

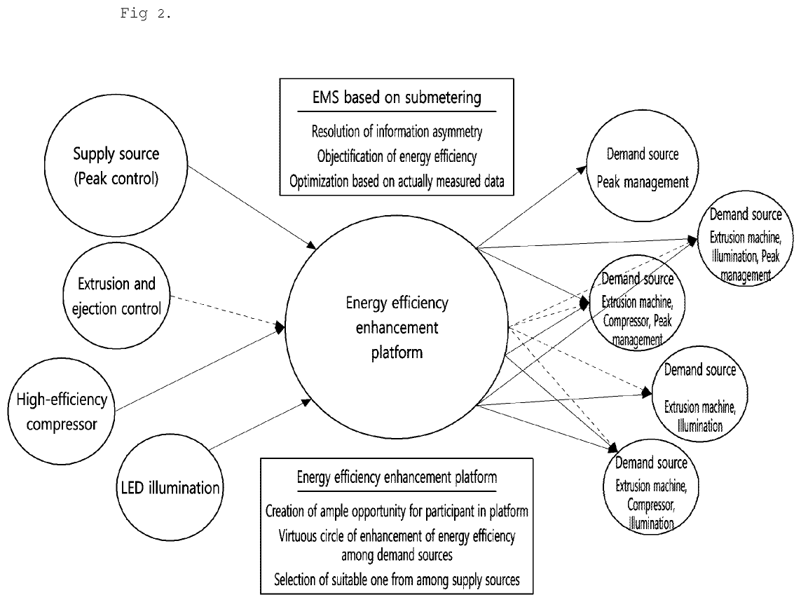

FIG. 2 is a diagram illustrating an energy-efficiency enhancement platform system based on submetering data according to an embodiment of the present invention. As illustrated in FIG. 2, in the energy-efficiency enhancement platform system based on the submetering data according to the embodiment of the present invention, the demand source and the supply source share the submetering data that is data actually measured on a per-equipment basis, through an energy-efficiency enhancement platform, thereby resolving information asymmetry. In the energy-efficiency enhancement platform system, the demand source needs to enhance energy efficiency, and the supplier provides at least one of energy-efficiency enhancement equipment, an energy management system, and an energy diagnosis consulting service. In addition, an energy-efficiency enhancement plan is optimized on the basis of the submetering data that is the actually-measured data. Processes of implementing the energy-efficiency enhancement plan are tracked and analyzed to verify whether or not energy efficiency is enhanced, and thus the energy efficiency is objectified. More specifically, the supply source recognizes a characteristic of the demand source and precisely targets a potential custom. Thus, a business volume can also be increased with keeping an operating cost low, and a supply price can be lowered. In addition, the demand source not only obtains energy-efficiency enhancement information on already-installed equipment, but also selects an optimal solution and supplier, thereby preventing overlapping investments.

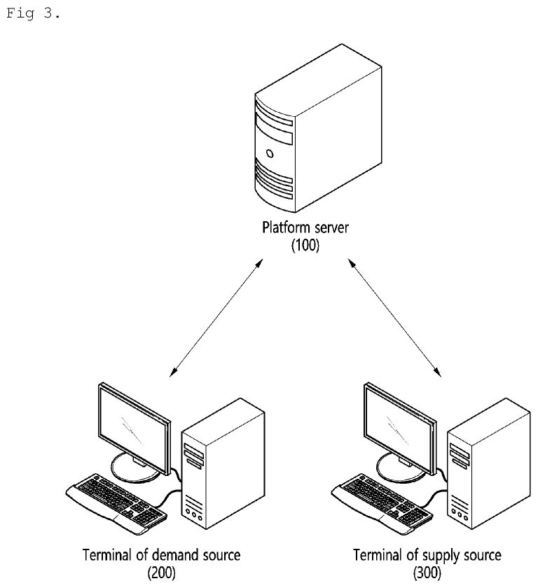

FIG. 3 is a diagram illustrating a configuration of the energy-efficiency enhancement platform system based on the submetering data according to the embodiment of the present invention. As illustrated in FIG. 3, the energy-efficiency enhancement platform system based on the submetering data according to the embodiment of the present invention may include a platform server 100 and may include a demand source terminal 200 and a supply source terminal 300.

Through the energy-efficiency enhancement platform, the platform server 100 enables the demand source, which needs to enhance the energy efficiency and the supply source, which provides at least one of the energy-efficiency enhancement equipment, the energy management system, and the energy analysis consulting service, to share the submetering data. That is, the platform server 100 manages a multiple-sided platform in which the demand source and the supply source are users, and thus the demand source and the supply source share the submetering data through interaction therebetween. The information asymmetry is accordingly resolved.

The submetering data here means “data behind the meter” and refers to data actually measured in an apparatus or a system, which measures electric power or energy on a per-equipment basis, other than a watt-hour meter under the control of Korea Electric Power Corporation (KEPCO). The platform server 100 according to the present invention uses the submetering data, as the data actually measured on a per-equipment basis, that is objective and quantitative data. Because of this, the platform server 100 provides a high-reliability service based on the objective and quantitative data.

Therefore, the energy-efficiency enhancement platform under the management of the platform server 100 enables the data actually measured with submetering at the demand source to be shared on line. Thus, the energy-efficiency enhancement platform is an online-to-offline (O2O) platform that is expected to resolve the information asymmetry and to improve the efficiency of the energy-efficiency enhancement market.

The demand source terminal 200 is a terminal of the demand source that needs to enhance the energy efficiency. The demand sources include various types of factories and buildings and are categorized by a type of business and size. Normally, the demand sources that are of the same type of business have similar equipment. In some cases, factories, buildings, and the like have general equipment. The demand source has access to the energy-efficiency enhancement platform under the management of the platform server 100 using the demand source terminal 200. Accordingly, the demand source is provided with an energy-efficiency enhancement plan and a result thereof for another demand source that is of a similar type of business, or with an energy-efficiency enhancement plan. The demand source may make a request for a necessary energy saving plan.

The supply source terminal 300 is a terminal of the supply source that provides at least one of the energy-efficiency enhancement equipment, the energy management system and the energy analysis consulting service. The demand source has access to the energy-efficiency enhancement platform under the management of the platform server 100 using the supply source terminal 300. Accordingly, the demand source is provided with analysis data that results from the platform server 100 analyzing the submetering data and provides an energy-efficiency enhancement plan that is optimized for a type of business or for a demand source that is of that type of business. This serves to target a potential customer. At this point, the supply source terminal 300 may directly download the submetering data for use or may review it on line. The analysis data in the platform server 100 may also be downloaded or be reviewed on line.

On the other hand, the demand source terminal 200 and the supply source terminal 300 have access to the energy-efficiency enhancement platform under the management of the platform server 100 through a network. The networks here include wired networks, such as a Local Area Network (LAN), a Wide Area Network (WAN), and a Value Added Network (VAN), and all types of wireless networks, such as a mobile radio communication network, a satellite network, Bluetooth, Wireless Broadband Internet (Wibro), High Speed Downlink Packet Access (HSDPA), Long Term Evolution (LTE) and 5th Generation Mobile Telecommunication (5G).

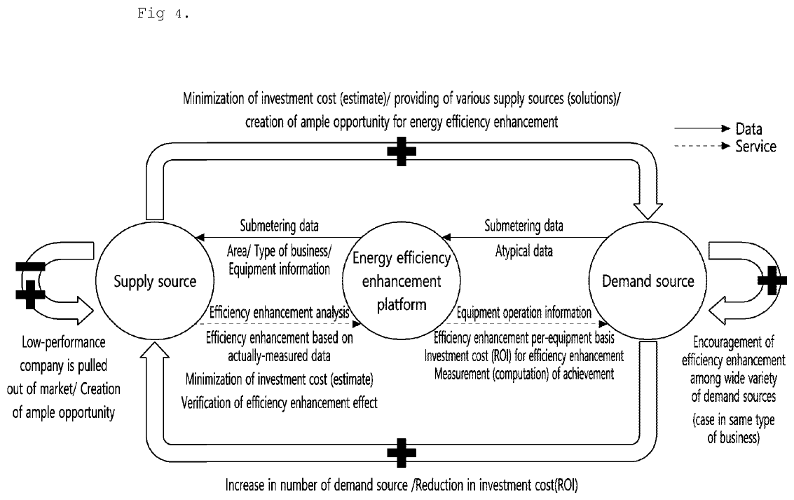

FIG. 4 is a diagram illustrating the respective flows of data and a service between each constituent element of the energy-efficiency enhancement platform system based on the submetering data according to the embodiment of the present invention. As illustrated in FIG. 4, the platform server 100 in the energy-efficiency enhancement platform system based on the submetering data according to the embodiment of the present invention manages the energy-efficiency enhancement platform provided by the platform server 100. Thus, the platform server 100 provides the supply source with the submetering data that is the data actually measured on a per-equipment basis at the demand source, and is provided with an energy-efficiency enhancement proposal that results from the analysis of the efficiency enhancement analysis based on the submetering data, from the supply demand. Accordingly, the platform server 100 provides the energy-efficiency enhancement proposal to the demand source. In addition, through the energy-efficiency enhancement platform, with reference to a case in a type of business to which the demand source belongs, the demand source is encouraged to enhance the energy efficiency. This increases the reliability of the energy-efficiency enhancement plan and makes it possible to provide an opportunity to encourage energy efficiency enhancement among a wide variety of demand sources. On the other hand, through the energy-efficiency enhancement platform, the demand source and the supply source share data, and match for service is made between the demand source and the supply source. Thus, the demand source can select an optimal solution from among solutions that are provided by various supply sources. Accordingly, low-performance supply sources are pulled out of the market. A cost is lowered and the energy-efficiency enhancement market grows with the decreasing cost.

Table 1 shows a comparison between a function of the energy-efficiency enhancement platform system based on the submetering data according to the embodiment of the present invention and a function of an existing system. From Table 1, it can be understood that the use of the energy-efficiency enhancement platform (the O2O platform) according to the present invention makes a change to the energy-efficiency enhancement market to an existing direct marketing policy is applied. Accordingly, the respective complaints and requirements of the demand source and the supply source are handled and satisfied, respectively. This contributes to enlarge the energy-efficiency enhancement market and create a new market.

TABLE 1

| | | | Complaint | O2O |
|---|---|---|---|---|
| Participant in efficiency | | Existing | and | platform |
| enhancement market | | way | requirement | function |
| Led by demand | Factory | Review of | In | Quantifi- |
| source | Building | energy | sufficient | cation |
| | | saving plan | technical | of results of |
| | | dependent | verification | energy |
| | | on proposal | of supply | efficiency |
| | | by supply | source's | enhancement |
| | | source | proposal | by |
| | | | uncertainty | supply |
| | | | of ROI | source, and |
| | | | High | creating |
| | | | investment | database |
| | | | cost | thereof |
| | | Search by | Information | Providing |
| | | demand | asymmetry | pieces of |
| | | source for | and | information |
| | | supply | insufficient | on multiple |
| | | source | amount of | demand |
| | | | information | sources |
| | | | on supply | in need |
| | | | source | for |
| | | | Low | energy |
| | | | reliability | efficiency |
| | | | of supply | enhance- |
| | | | source and | ment |
| | | | low ROI | |
| Led by supply | Energy | Search by | Increasing | Multiple |
| source | efficiency | supply | expenses due | demand |
| | enhance- | source and | to low late | sources |
| | ment | its partner | of | Competitive |
| | equipment | for demand | successful | edge |
| | | source | business | due to |
| | | | Absence of | decrease |
| | | | energy | in |
| | | | efficiency | operating |
| | | | computation | cost |
| | | | system | |
| | | | Incurring | |
| | | | of | |
| | | | opportunity | |
| | | | cost of | |
| | | | developing | |
| | | | business | |
| | | | with demand | |
| | | | source | |
| | EMS | System | Increasing | Reduction in |
| | company | development | cost of | installation |
| | | at demand | customizing | cost and |
| | | source's | EMS system | management |
| | | request | for demand | cost due to |
| | | | source | use of cloud |
| | | | Fluctuation | EMS |
| | | | in sales | |
| | | | to project | |
| | | | dependent | |
| | | | business | |
| | Energy | Consulting | One-time | Reduction in |
| | analysis | provided by | analysis and | analysis cost |
| | and | supply | consulting | due to data |
| | consulting | source and | project- | collection at |
| | | government- | centered | all times and |
| | | funded | analysis | creation of |
| | | consulting | High-cost | maintenance |
| | | | structure | market |
| | | | for | |
| | | | manpower- | |
| | | | based | |
| | | | business | |

| | |
|---|---|
| O2O | Through an energy efficiency enhancement platform, |
| platform/market | bidirectional information asymmetry between a demand |
| | source that is a platform user, and a supply source |
| | is resolved. |
| | Pieces of data on the demand source are provided |
| | and reliability is increased due to quantification |
| | of results of efficiency enhancement of supplied |
| | energy. |
| | Redundant investments by market participants are |
| | prevented and an optimal solution and investment |
| | cost are provided to each market participant. |
| | Due to an effect of one-to-one matching among |
| | platform users, an energy-efficiency enhancement |
| | market grows with a decreasing cost. |

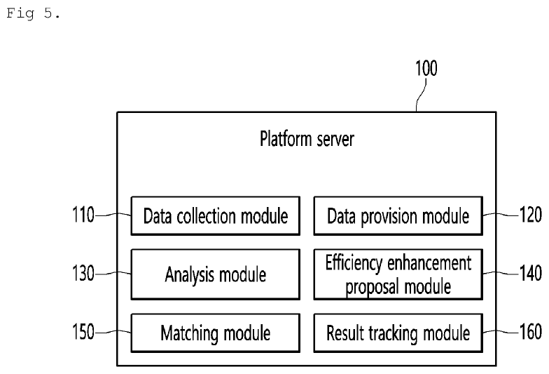

FIG. 5 is a diagram illustrating a detailed configuration of the platform server 100 in the energy-efficiency enhancement platform system based on the submetering data according to the embodiment of the present invention. As illustrated in FIG. 5, the platform server 100 in the energy-efficiency enhancement platform system based on the submetering data according to the embodiment of the present invention includes a data collection module 110, a data provision module 120, an analysis module 130, and an efficiency enhancement proposal module 140. The platform server 100 may further include a matching module 150 and a result tracking module 160.

The data collection module 110 collects the submetering data that is the data actually measured on a per-equipment basis, from the demand source. The data collection module 110 performs tagging on the collected submetering data according to types of equipment and to a rating for storing and managing the data.

The data provision module 120 provides the supply source with the collected submetering data. However, the data provision module 120 provides the supply source with the collected submetering data, but the collected submetering data as non-identification data with which an individual demand source is unidentifiable. This prevents information on each demand source from being excessively disclosed and prevents a transaction from being made outside of the energy-efficiency enhancement platform. Such a transaction is possible because demand source is identified by the supply source.

In addition, the data provision module 120 provides the supply source with the submetering data that results from categorization by at least one of a type of equipment, a type of business, and a rating. In addition, pieces of submetering data on which tapping are performed according to a type of business of the supply source are categorized, and the resulting necessary data is provided. For example, the supply source, if it is a compressor-related company, is provided with the submetering data on a compressor. This prevents unauthorized divulge of data other than the submetering data on the compressor and makes it possible to efficiently share the submetering data.

According to an embodiment, the data provision module 120 conducts a search for a search word, a category, and the like that are input from the demand source or the supply source, and provides the demand source or the supply source with data that is found as a result of conducting a search. At this time, the data provision module 120 sets a search level to vary according to the authority of the demand source or the supply source.

On the other hand, the data provision module 120 provides the supply source with the submetering data that results from analysis on the basis of type of equipment, type of business, and season and time by the analysis module 130 that will be described below. For example, the supplier, if it is an energy-efficiency enhancement-related company, is provided with results that are obtained by the data provision module 120 analyzing pieces of energy monitoring data on various demand sources, energy data on each equipment item of each demand source, and the like. In addition, the supplier, if it is an energy-efficiency enhancement-related company, may be provided with data for energy consulting, which results from the analysis of the submetering data.

The analysis module 130 analyzes the energy-efficiency enhancement proposal received from the supplier demand and the collected submetering data. That is, the supply source analyzes the submetering data provided by the data provision module 120 and uploads the energy-efficiency enhancement proposal to the energy-efficiency enhancement platform. The analysis module 130 analyzes the energy-efficiency enhancement proposal uploaded by the analysis module 130. Particularly, the analysis module 130 quantitatively analyzes the energy-efficiency enhancement proposal received from the supply source on the basis of the submetering data collected from the demand source. Therefore, since the energy-efficiency enhancement proposal received from the supply source is quantitatively analyzed on the basis of the actually-measured data, the energy-efficiency enhancement proposal is optimized for the demand source, and thus the reliability thereof is increased.

The efficiency enhancement proposal module 140 provides the demand source with the energy-efficiency enhancement proposal on the basis of the result of the analysis by the analysis module 130. Particularly, the efficiency enhancement proposal module 140 proposes to the demand source the energy-efficiency enhancement plan. The energy-efficiency enhancement plan includes a result of the quantitative analysis that is obtained by analyzing the energy-efficiency enhancement proposal received from the supply source on the basis of the submetering data received by the analysis module 130 from demand source. According to an embodiment, the energy-efficiency enhancement plan is generated in the form of a report or proposal and is proposed to the demand source. At this time, the energy-efficiency enhancement plan includes a return on investment (ROI). In addition, the energy-efficiency enhancement plan includes an energy-efficiency enhancement plan on a per-type-of-business basis and an individual energy-efficiency enhancement plan on a per-equipment basis, which are based on the submetering data. Therefore, the demand source selects the supply source according to the respective specific proposals for a type of business and equipment. This helps the demand source to make a decision for investment.

On the other hand, the efficiency enhancement proposal module 140 provides the demand source with an energy-efficiency enhancement method and a result thereof for the demand source and for a type of business to which the demand source belongs. In most cases, the demand sources belonging to the same industrial classification have similar equipment. Therefore, a specific energy-efficiency enhancement method, a result thereof, and the like for a type of business to which the demand source belongs are provided. This increases the reliability of the energy-efficiency enhancement plan and makes it possible to provide an opportunity to encourage energy efficiency enhancement among a wide variety of demand sources. The specific energy-efficiency enhancement method can be employed for an excellent benchmarking model case.

The matching module 150 matches the supply source selected by the demand source and the demand source. That is, on the basis of the energy-efficiency enhancement proposal received from the supply source and of the analysis result of the analysis by the analysis module 130, the matching module 150 provides the demand source in need for the energy-efficiency enhancement proposal by the supply source with the energy-efficiency enhancement plan by the supply source, and matches the supply source selected by the demand source and the demand source, in conjunction with the efficiency enhancement proposal module 140. In addition, when the demand source makes a request for the energy-efficiency enhancement, the matching module 150 may recommend the supply source in conjunction with the analysis module 130 and the efficiency enhancement proposal module 140. At this time, the matching module 150 may match multiple supply sources with one demand source and may match one supply source to multiple demand sources.

The result tracking module 160 tracks and analyzes the processes of implementing the energy-efficiency enhancement plan by the supply source and computes an amount of saving. In the energy-efficiency enhancement platform system based on the submetering data according to the embodiment of the present invention, the result of the efficiency enhancement is tracked on the energy-efficiency enhancement platform and thus an amount of energy saving is computed. Furthermore, it is checked whether or not the result that is obtained after installing equipment and so on is consistent with the energy-efficiency enhancement proposal by the supply source. Then, the supply source or the energy-efficiency enhancement equipment is evaluated, thereby setting a rating.

The computation here of the amount of savings means subtracting total costs and expenses incurred after the efficiency enhancement of the equipment from total costs and expenses incurred before the efficiency enhancement of the equipment. When the costs and expenses for the energy-efficiency enhancement were paid in advance, the amount of energy saving may be paid back. In addition, the ROI is computed by dividing the amount of investment by the amount of saving, and thus the result tracking module 160 computes the ROI using the computed amount of saving and tracks and analyzes the energy ROI result at the demand source.

More precisely, an amount of saving of electric cost is obtained from an amount of saving of electric power usage. An amount of saving of electric power and the amount of saving of electric cost may vary in a nonlinear manner, depending on which one of seasonal and hourly billing systems is employed. On the other hand, for the amount of saving of electric power, an amount of electric power usage before the installation of the energy efficiency enhancement equipment is set as a reference amount as a baseline, and then a difference between an amount of electric power usage after installation of the energy efficiency enhancement equipment and the reference amount is computed. The amount of yearly or hourly electric power usage differs with a change in ambient temperature, even among the same equipment. Therefore, considering a difference between amounts of seasonal electric power usage and the like, it is reasonable that a reference amount is set on the basis of an amount of electric power usage for at least one year. For example, when a difference of approximately 30% occurs between amounts of hourly electric power usage by the equipment in summer and winter, the amount of saving of electric power, the amount of saving of electric cost, and the ROI vary greatly depending on whether the reference amount is set on the basis of an amount of electric power usage in summer or in winter. Therefore, in order to accurately analyze the ROI, it is important to set the amount of electric power usage that serves as a reference amount.

In an existing energy saving project, an amount of electric power usage for approximately two weeks is as a reference amount and an estimated amount of saving is then computed. Unlike the case with such a project, in the energy-efficiency enhancement platform system based on the submetering data according to the embodiment of the present invention, the supply source precisely sets a reference amount (baseline) in a state where amounts of electric power usage are secured based on the submetering data at the demand source during a long period of time. Therefore, the respective precisions of the estimated amount of saving and the ROI can be increased, and a proposal for efficiency enhancement can be provided on the basis of the precisely-set reference amount. Furthermore, the supply source can selectively select the demand source on the basis of the amounts of electric power usage secured for a long period of time.

In addition, the result tracking module 160 tracks and analyzes the energy ROI result obtained from the demand source and provides another demand source that belongs to the same type of business or has the same equipment. This makes it possible to provide an opportunity to encourage energy efficiency enhancement among a wide variety of demand sources.

In this manner, in the energy-efficiency enhancement platform system based on the submetering data according to the embodiment of the present invention, the demand source and the supply source share the submetering data through the energy-efficiency enhancement platform. Thus, the energy management based on the submetering, the data analysis on a per-type-of-business and per-equipment basis, and the energy-efficiency enhancement consulting service can be effectively provided. In addition, the processes of implementing the energy-efficiency enhancement plan by the supply source, provided through the prior analysis of the supply source data, can be tracked and analyzed. Thus, systematic managements can be performed, such as follow-up service, and efficiency computation, and ROI analysis.

As described above, in the energy-efficiency enhancement platform system based on the submetering data according to the embodiment of the present invention, the demand source and the supply source share the submetering data that is data actually measured on a per-equipment basis, through the platform server 100, thereby resolving the information asymmetry. The demand source needs to encourage energy efficiency enhancement, and the supplier provides at least one of the energy-efficiency enhancement equipment, the energy management system, and the energy diagnosis consulting service. With the energy-efficiency enhancement platform system, the supply source can recognize a characteristic of the demand source, and thus can precisely target a potential custom and can increase a business volume with keeping an operating cost low. Furthermore, the demand source can obtain the energy-efficiency enhancement information on the already-installed equipment, and thus can select the optimal solution and supply source at low cost and can prevent overlapping investments.

It is possible that a person of ordinary skill in the art to which the present invention pertains makes various modifications to the present invention described above and implements various applications thereof. The scope of the technical idea of the present invention should be defined by the following claims.

What is claimed is:

1. An energy-efficiency enhancement platform system based on submetering data, the system comprising a platform server through which a demand source that needs to enhance energy efficiency and a supply source that provides at least one of energy-efficiency enhancement equipment, an energy management system, and an energy analysis consulting service share submetering data, wherein the platform server comprises: a data collection module that collects the submetering data that is data actually measured on a per-equipment basis, from the demand source; a data provision module that provides the supply source with the collected submetering data; an analysis module that analyzes an energy-efficiency enhancement proposal received from the supply source and the collected submetering data; and an efficiency enhancement proposal module that provides the demand source with an energy-efficiency enhancement plan on the basis of a result of the analysis by the analysis module.

2. The energy-efficiency enhancement platform system according to claim 1, wherein the data provision module provides the supplier with the collected submetering data, but the collected submetering data as non-identification data with which an individual demand source is unidentifiable.

3. The energy-efficiency enhancement platform system according to claim 1, wherein the data provision module provides the supply source with the submetering data that results from categorization by at least one of a type of equipment, a type of business, and a rating.

4. The energy-efficiency enhancement platform system according to claim 1, wherein the analysis module quantitatively analyzes the energy-efficiency enhancement proposal received from the supply source, on the basis of the submetering data collected from the demand source, and
the efficiency enhancement proposal module proposes to the demand source the energy-efficiency enhancement plan that includes a result of the quantitative analysis.

5. The energy-efficiency enhancement platform system according to claim 4, wherein the energy-efficiency enhancement plan includes a return on investment (ROI).

6. The energy-efficiency enhancement platform system according to claim 1, wherein the efficiency enhancement proposal module provides the demand source with an energy-efficiency enhancement method and a result thereof for a type of business to which the demand source belongs.

7. The energy-efficiency enhancement platform system according to 1, wherein the energy-efficiency enhancement plan includes an energy-efficiency enhancement plan on a per-type-of-business basis and an energy-efficiency enhancement plan on a per-equipment basis, which are based on the submetering data.

8. The energy-efficiency enhancement platform system according to 1, further comprising a matching module that matches the supply source selected by the demand source and the demand source.
